(19) United States
(12) Patent Application Publication
(10) Pub. No.: US 2025/0168961 A1
(43) Pub. Date: May 22, 2025

(54) METHOD FOR IGNITING AND/OR MAINTAINING A PLASMA USING A PULSED HIGH-FREQUENCY SIGNAL, POWER GENERATOR, AND PLASMA ARRANGEMENT

(71) Applicant: TRUMPF Hüttinger GmbH + Co. KG, Freiburg (DE)

(72) Inventor: Alexander Alt, Freiburg (DE)

(21) Appl. No.: 19/032,500

(22) Filed: Jan. 21, 2025

Related U.S. Application Data
(63) Continuation of application No. PCT/EP2023/070239, filed on Jul. 21, 2023.

(30) Foreign Application Priority Data
Jul. 21, 2022 (DE) 10 2022 118 340.8

(51) Int. Cl. H05H 1/46

(52) U.S. Cl. CPC H05H 1/4645

(57) ABSTRACT

A method for igniting and/or maintaining a plasma process using a pulsed high-frequency signal includes generating the pulsed high-frequency signal, changing a frequency of the high-frequency signal according to a frequency sweep and/or changing an amplitude of the high-frequency signal according to a power sweep during a predetermined first time interval within a pulse, monitoring at least one process parameter of the plasma process, determining a relationship of the at least one process parameter to the frequency sweep or the power sweep, and detecting whether the at least one process parameter having the relationship to the frequency sweep or the power sweep has assumed a predetermined value or is in a predetermined value range.

### CROSS REFERENCE TO RELATED APPLICATIONS

This application is a continuation of International Application No. PCT/EP2023/070239 (WO 2024/018042 A1), filed on Jul. 21, 2023, and claims benefit to German Patent Application No. DE 10 2022 118 340.8, filed on Jul. 21, 2022. The aforementioned applications are hereby incorporated by reference herein.

### FIELD

Embodiments of the present invention relate to a method for igniting and/or maintaining a plasma using a pulsed high-frequency signal. Embodiments of the present invention also relate to a power generator and a plasma arrangement.

### BACKGROUND

In plasma processes using pulsed sources, an impedance trajectory dependent on the process parameters is passed through during a pulse. The goal is to reliably ignite a plasma and then land in the adapted state without having to readjust an impedance matching network.

How rapidly a plasma ignites and how stable the plasma process is depending on the form of a pulsed high-frequency signal. FIG. 1a shows a typical course of the power of a pulsed high-frequency signal. FIG. 1b shows the typical course of the frequency of a pulsed high-frequency signal and FIG. 1c shows the typical course of the absolute value of the reflection factor. A multistage pulse is often used to ignite and operate a plasma in the prior art, wherein an attempt is made to ignite a plasma in a first time interval, which is identified by I in FIGS. 1a, b, c. For this purpose, energy is supplied to a plasma chamber during the first time interval I and a second time interval II. The time intervals can also be used to achieve various plasma operating states. The power and frequency of the time intervals are manually optimized if needed in the prior art. The frequency and amplitude of the high-frequency signal are not changed during the duration of a time interval I, II. The durations of the time intervals I, II have also been manually optimized if needed up to this point.

A plasma process can be supplied with power during the second time interval II. Frequency and amplitude of the high-frequency signal are designed here so that the plasma can be assumed to be stable during the second time interval II and impedance matching exists.

The plasma parameters change during the first time interval I. The plasma is unignited at the beginning of the first time interval I. The impedance is thus high. At the end of the first time interval I, the impedance approaches the system impedance after the ignition of the plasma. This can be seen from the falling absolute value of the reflection factor according to FIG. 1c. The changing impedance of the plasma results in the above-mentioned impedance trajectory.

### SUMMARY

Embodiments of the present invention provide a method for igniting and/or maintaining a plasma process using a pulsed high-frequency signal. The method includes generating the pulsed high-frequency signal, changing a frequency of the high-frequency signal according to a frequency sweep and/or changing an amplitude of the high-frequency signal according to a power sweep during a predetermined first time interval within a pulse, monitoring at least one process parameter of the plasma process, determining a relationship of the at least one process parameter to the frequency sweep or the power sweep, and detecting whether the at least one process parameter having the relationship to the frequency sweep or the power sweep has assumed a predetermined value or is in a predetermined value range.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1a shows the power of a conventional pulsed high-frequency signal;

FIG. 1b shows the frequency of a conventional pulsed high-frequency signal;

FIG. 1c shows the course of the absolute value of the reflection factor as a result of the courses of power and frequency shown in FIGS. 1a and 1b;

FIG. 2a shows the course of the power of a pulsed high-frequency signal with variation of the amplitude of the high-frequency signal according to a power sweep, according to some embodiments;

FIG. 2b shows the course of the frequency of a high-frequency signal, wherein the frequency is varied according to a frequency sweep, according to some embodiments;

FIG. 2c shows the course of the reflection factor corresponding to the signal courses of FIGS. 2a and 2b, according to some embodiments;

FIG. 3a shows a power course (power sweep), which is varied in sections, of a pulsed high-frequency signal, according to some embodiments;

FIG. 3b shows a frequency course (frequency sweep), which is varied in sections, of a pulsed high-frequency signal, according to some embodiments; and

FIG. 4 schematically shows a plasma arrangement according to some embodiments.

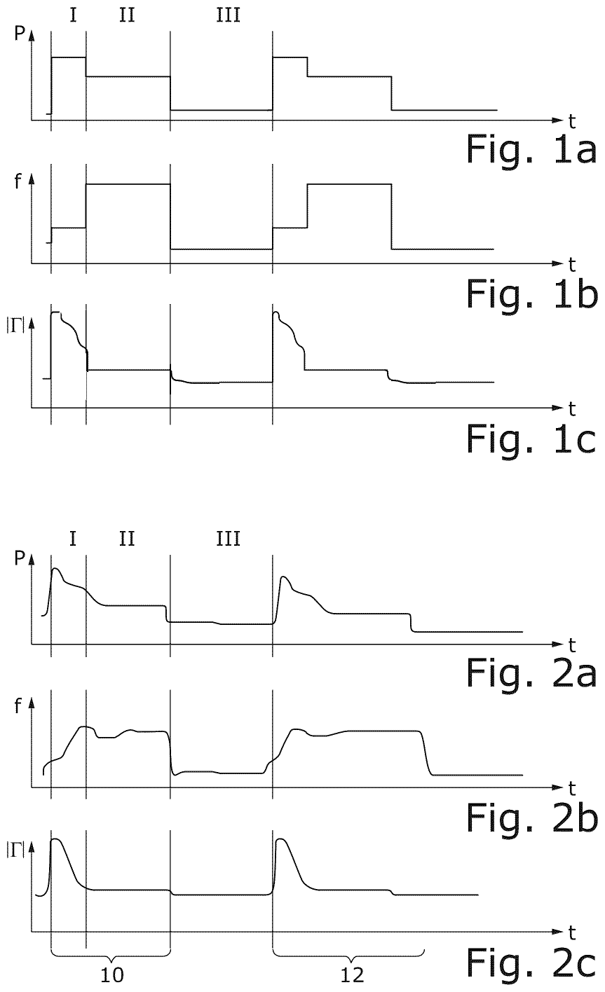

### DETAILED DESCRIPTION

Embodiments of the present invention provide a method and a power generator using which the ignition and feeding of a plasma with energy can be improved.

According to embodiments of the invention, a method for igniting and/or maintaining a plasma using a pulsed high-frequency signal comprises the following method steps:
a) generating a pulsed high-frequency signal,
b) changing the frequency of the high-frequency signal according to a frequency sweep and/or the amplitude of the high-frequency signal according to a power sweep during a predetermined first time interval within a pulse,
c) monitoring at least one process parameter of the plasma process,
d) determining a relationship of the process parameter to the performed sweep, and
e) detecting whether the monitored process parameter(s) having a relationship to the sweep(s) assume a predetermined value or are in a predetermined value range.

A high-frequency signal herein refers to a signal having a frequency of 1 MHz or higher. The high-frequency signal preferably has a frequency in the range 10-100 MHz.

A pulsed high-frequency signal herein refers to a high-frequency signal that is modulated in the form of pulses. A possible generation of such a pulsed high-frequency signal is described, for example, in U.S. Pat. No. 8,884,523 B2. A pulsed high-frequency signal can be pulsed at a frequency of up to 500 kHz. A pulsed high-frequency signal can be pulsed in multiple power levels.

In the first time interval, the frequency can vary by ±30%, in particular ±20%, preferably ±10%. The amplitude of the high-frequency signal can also vary in the first time interval by ±30%, in particular ±20%, preferably ±10%.

A sweep herein refers to a change over time of a variable, which is predetermined or adapted to measured values, in a predetermined period of time. A “change over time” is to be understood as a change of the variable in the course of the period of time. A frequency sweep is accordingly a change over time of the frequency, which is predetermined or adapted to the measured values, during the duration of a predetermined period of time, for example, the first and/or second time interval. A power sweep is accordingly a change over time of the amplitude of a high-frequency signal, which is predetermined or adapted to the measured values, in a predetermined period of time, for example, the first and/or second time interval.

Determining a relationship of the process parameter to the performed sweep can comprise the detection of the plasma parameter and the performance of the sweep having a chronological relationship, for example, taking place simultaneously or with chronological overlap. A relationship of a process parameter and a sweep can also be that a process parameter changes as a function of the change over time of the frequency or the amplitude of the high-frequency signal during the sweep. For example, a process parameter can change during the ignition of the plasma, wherein a specific frequency and/or amplitude value of the high-frequency signal can accompany the ignition of the plasma. A relationship of a process parameter and a sweep can also be determined in that a correlation algorithm determines such a relationship.

The detection whether the monitored process parameter(s) each assume a predetermined value or are in a predetermined value range can give an indication whether a sweep has to be changed to improve the process, for example, to ignite the plasma.

The sweep(s) can be assessed on the basis of their detection, in particular their detection in step v. In particular, it can be assessed whether a sweep has resulted in a good or bad, a better or worse process behavior than a preceding sweep. In addition, it is possible to study at which time during a sweep an ignition has taken place. The effects of a sweep on one or more process parameters can be determined. These effects can only occur after some time, for example, after ending a sweep. A relationship of a process parameter and a sweep can also be that a sweep has no effect on a process parameter.

For following pulses and/or for a second time interval of a pulse, in particular of the first pulse or a further pulse, a sweep can be selected on the basis of the assessment of one or more preceding sweeps. A changed sweep can therefore be set for following pulses and/or time intervals on the basis of the analysis of preceding sweeps. A second time interval can be suitable for the normal operation of the plasma, i.e. to maintain the plasma. Impedance matching can be provided for this purpose.

The assessment can include an examination of the sweep on the basis of the detection, in particular detection according to step v. In particular, it can thus be determined at which point in time of a sweep a process parameter displays a specific behavior.

The duration of the time intervals can be adapted on the basis of the assessment for following pulses. For example, if it has been recognized that the ignition of a plasma already takes place very early during a frequency sweep or power sweep of a pulse, the first time interval can be shortened for a following pulse. More energy can therefore be supplied to a plasma, since, for example, a second time interval can be lengthened accordingly.

The frequency of the high-frequency signal can be changed according to a frequency sweep and/or the amplitude of the high-frequency signal can be changed according to a power sweep during a predetermined second time interval within the pulse. An optimum feed of the plasma with energy can thus be achieved. The two different sweeps can preferably be performed in succession.

Steps c)-e) can additionally be performed in the second time interval. More analysis data are therefore available and the second time interval can be set for following pulses or the frequency sweep and/or the power sweep can be set for the second time interval of following pulses in order to achieve specific target process parameter values.

A different frequency sweep and/or a different power sweep can be used for at least one further pulse than for a preceding pulse, in particular for a first pulse. By comparing the situation to the preceding pulse, it can be determined whether the plasma process was changed, in particular was improved or worsened. The frequency sweep and/or the power sweep can be adapted for following pulses depending on the result of this analysis.

Different frequency sweeps and/or power sweeps can be set until the monitored process parameter(s) achieve predetermined values or value ranges. This can be done until optimal process parameters are achieved. It is conceivable to change the target values for process parameters. An optimization can thus take place during the plasma process.

A frequency sweep and/or a power sweep suitable for igniting a plasma can be determined in a calibration process. Suitable frequency and/or power sweeps can thus be determined outside a plasma process.

In particular, one or more of the following process parameters can be monitored: Ignition behavior of the plasma, power loss of the generator generating the pulsed high-frequency signal, reflection factor, amplitude of the high-frequency signal, relative phase between outgoing and returning wave of the pulsed high-frequency signal.

The analysis can be facilitated if the frequency and/or the amplitude are changed continuously during the frequency sweep and/or power sweep.

The frequency sweep and/or the power sweep can have multiple sections, wherein the frequency and/or the amplitude are each constant in the sections. A section can comprise multiple periods of the high-frequency signal here. In principle, it is possible to observe the high-frequency signal period by period. However, the detection of the process parameters and a regulation are greatly simplified if the signal is instead generated and measured/detected in sections, wherein the sections each consist of multiple periods of the high-frequency signal which do not differ in set power and/or frequency within the section.

At least some sections can be of different lengths, in particular increasing in chronological length in the course of a pulse. For example, sections at the beginning of the first time interval of the pulse can be shorter than sections lying at the end of the first time interval and possibly in the second time interval. The length of the sections can therefore be adapted to the dynamics of the plasma.

According to some embodiments, a power generator for a plasma arrangement is configured to
a) generate a pulsed high-frequency signal,
b) change the frequency of the high-frequency signal according to a frequency sweep and/or change the amplitude of the high-frequency signal according to a power sweep during a predetermined first time interval within a pulse,
c) generate a frequency sweep and/or a power sweep as a function of at least one detected process parameter.

The method according to embodiments of the invention can be performed well using such a power generator.

The power generator can have a digital-to-analog converter for generating the pulsed high-frequency signal. The signal thus generated can be amplified. This permits the control of the amplitude of the high-frequency signal and the frequency of the high-frequency signal. In particular, frequency and power sweeps can be set easily using such a power generator.

Alternatively, the power generator for generating the pulsed high-frequency signal can comprise a direct digital synthesizer (DDS) with connected amplitude modulation unit.

In addition, a plasma arrangement comprising a power generator according to the embodiments of the invention, a plasma chamber, and an impedance matching arrangement arranged between the power generator and the plasma chamber is provided. A detection device can be provided for detecting at least one process parameter. Furthermore, the power generator can be configured to generate a frequency sweep and/or a power sweep as a function of the at least one detected process parameter.

Exemplary embodiments of the invention are described below, with reference to the figures of the drawing. The various features can be realized in each case individually by themselves or as a plurality in any desired combinations.

FIG. 2a shows that during a first time interval I, the amplitude of a pulsed high-frequency signal and as a result the power was varied during a pulse 10. In the first time interval I, the amplitude of the high-frequency signal is therefore varied according to a power sweep. In contrast, during a second time interval II of the pulse, the amplitude of the pulsed high-frequency signal is not varied. The third time interval III can represent a pulse pause of the pulsed high-frequency signal. No power would then be supplied to the plasma process in the pulse pause. Alternatively, it is possible that in this third time interval III, a further power, which differs from the power of the second time interval II, is supplied to the plasma process.

Very fundamentally, it is possible to switch between multiple power levels in a pulse signal. Plasma processes are known in which switches are made between two, preferably three, in particular four or more power levels. Individual time intervals (not shown in the figures) can also be defined for this purpose. In each of these time intervals, the frequency can be changed according to a frequency sweep, in particular according to an above-described generated frequency sweep.

In each of these time intervals, the amplitude can additionally or alternatively be changed according to a power sweep, in particular according to an above-described generated power sweep.

It can be seen in FIG. 2b that the frequency of the pulsed high-frequency signal was changed during the first time interval I during the pulse 10. The frequency was therefore changed according to a frequency sweep. The frequency was also varied according to a frequency sweep in the second time interval II. A first sweep, for example, a frequency sweep can be performed here in the first time interval I and a second sweep different from the first sweep, for example, a power sweep can be performed in the second time interval II, or vice versa. Alternatively, it is possible that both sweeps are performed in at least one time interval.

It can be seen from FIG. 2c that the absolute value of the reflection factor is very high at the beginning of the first time interval I and then drops strongly. The drop of the absolute value of the reflection factor is therefore related to the plasma being ignited. It can be determined by a corresponding analysis at which frequency and which amplitude of the pulsed high-frequency signal the ignition took place. To improve the ignition behavior, a different frequency sweep and/or power sweep can be used for the following pulse 12. In addition, the chronological length of the first and/or second time interval I, II can be changed to improve the plasma process.

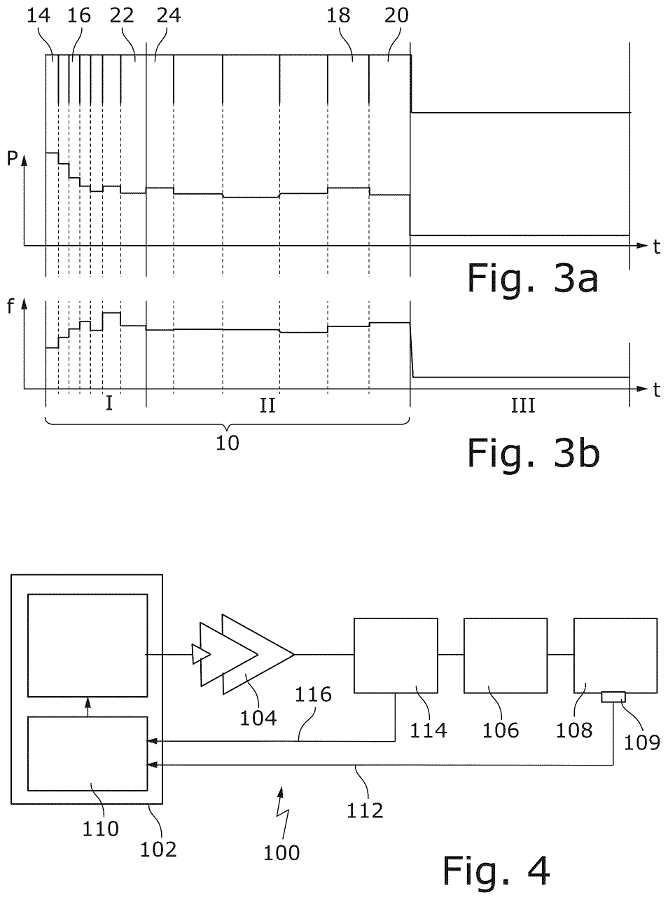

FIG. 3a shows a power sweep in the time interval I, wherein the power and accordingly the amplitude of the high-frequency signal has multiple sections 14, 16. The power or amplitude is constant in each section 14, 16. The sections 14, 16 at the beginning of the pulse 10 are chronologically shorter than the sections 18, 20 at the end of the pulse 10. The section 22 at the end of the first time interval I can be chronologically longer here than the first section 14 at the beginning of the first time interval I. The section 22 can be equal to or shorter than the time section 24 at the beginning of the second time interval II.

FIG. 3b shows the course of the frequency of the pulsed high-frequency signal. The frequency also changes from section to section 14-24. However, the frequency is constant within a section 14-24. In FIGS. 3a, 3b, the sections 14-24 for the power and the frequency are of equal lengths. However, it is also conceivable to select sections 14-24 of different lengths for the power than for the frequency.

FIG. 4 shows a plasma arrangement 100 having a power generator 102. The power generator 102 is configured to generate a pulsed high-frequency signal, wherein different frequency sweeps and/or power sweeps can be set for the individual pulses of the high-frequency signal. The pulsed high-frequency signal can be amplified by an amplifier 104 and supplied via an impedance matching arrangement 106 to a plasma chamber 108. Processing parameters can be detected directly at the plasma chamber 108 by a detection unit 109 and supplied to an evaluation unit 110, which is indicated by the arrow 112. Further process parameters, in particular electrical parameters, can be detected by a detection unit 114 designed as a measuring unit and given to the evaluation unit 110, which is symbolized by the arrow 116.

The detected processing parameters and the pulsed high-frequency signal, in particular individual pulses of the pulsed high-frequency signal, can be related to one another in the evaluation unit 110. It can be determined from this analysis whether and in which way the generation of the pulses of the pulsed high-frequency signal has to be changed to improve the plasma process.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for igniting and/or maintaining a plasma process using a pulsed high-frequency signal, the method comprising:
generating the pulsed high-frequency signal,
changing a frequency of the high-frequency signal according to a frequency sweep and/or changing an amplitude of the high-frequency signal according to a power sweep during a predetermined first time interval within a pulse,
monitoring at least one process parameter of the plasma process,
determining a relationship of the at least one process parameter to the frequency sweep or the power sweep, and
detecting whether the at least one process parameter having the relationship to the frequency sweep or the power sweep has assumed a predetermined value or is in a predetermined value range.

2. The method as claimed in claim 1, further comprising assessing the frequency sweep and/or the power sweep based on the detecting.

3. The method as claimed in claim 2, further comprising, for following pulses and/or for a second time interval of the pulse, selecting a sweep based on the assessing.

4. The method as claimed in claim 2, wherein the assessing includes an examination of the frequency sweep or the power sweep based on the detecting.

5. The method as claimed in claim 3, wherein a duration of the first time interval or the second time interval is adapted based on the assessing for the following pulses.

6. The method as claimed in claim 1, wherein a different frequency sweep and/or a different power sweep are set until the at least one process parameter achieves the predetermined value or is in the predetermined value range.

7. The method as claimed in claim 1, wherein the frequency sweep and/or the power sweep suitable for igniting the plasma process is determined in a calibration process.

8. A power generator for a plasma arrangement, the power generator being configured to:
generate a pulsed high-frequency signal,
change a frequency of the high-frequency signal according to a frequency sweep and/or change an amplitude of the high-frequency signal according to a power sweep during a predetermined first time interval within a pulse, and
generate a target frequency sweep and/or a target power sweep as a function of at least one detected process parameter.

9. The power generator as claimed in claim 8, comprising a direct digital synthesizer (DDS) with a connected amplitude modulation unit.

10. A plasma arrangement comprising:
a power generator as claimed in claim 8,
a plasma chamber, and
an impedance matching arrangement arranged between the power generator and the plasma chamber.
